(19) United States
(12) Patent Application Publication
(10) Pub. No.: US 2014/0050850 A1
(43) Pub. Date: Feb. 20, 2014

(54) VACUUM APPARATUS, METHOD FOR COOLING HEAT SOURCE IN VACUUM, AND THIN FILM MANUFACTURING METHOD

(71) Applicant: Panasonic Corporation, Osaka (JP)

(72) Inventors: Kazuyoshi Honda, Osaka (JP); Sadayuki Okazaki, Osaka (JP); Kunihiko Bessho, Osaka (JP); Takashi Shimada, Osaka (JP)

(21) Appl. No.: 13/985,794

(22) PCT Filed: Sep. 27, 2012
(86) PCT No.: PCT/JP2012/006208

§ 371 Date: Aug. 15, 2013

(30) Foreign Application Priority Data
Nov. 15, 2011 (JP) 2011-249561

(51) Int. Cl. C23C 16/44; F28D 1/00

(52) U.S. Cl. CPC C23C 16/44; F28D 1/00
USPC 427/248.1; 118/724; 165/132

(57) ABSTRACT

A vacuum apparatus (100) includes: a vacuum chamber (11); a heat source (12) disposed inside the vacuum chamber (11); a cooling device (20) that cools the heat source (12) by circulation of a cooling gas; a gas feed line (1) connected to the cooling device (20) and extending outside the vacuum chamber (11); a cooling gas feeder (14) that feeds the cooling gas to the cooling device (20) through the gas feed line (1) when the heat source (12) is to be cooled; and a vacuum pump (13) that evacuates the cooling device (20) when the heat source (12) is to be used.

### TECHNICAL FIELD

The present invention relates to a vacuum apparatus, a method for cooling a heat source in a vacuum, and a method for producing a thin film.

### BACKGROUND ART

Thin film techniques have been used widely to enhance the performance of devices and to reduce the size thereof. Thin film devices not only provide direct benefits to users but also play an important role in environmental aspects such as protection of earth resources and reduction in power consumption.

High-rate film deposition techniques are essential to increase the productivity of thin film formation. Attempts have been made to increase the deposition rate in various film formation methods such as a vacuum vapor deposition method, a sputtering method, an ion plating method, and a CVD (Chemical Vapor Deposition) method. A take-up type thin film production method has been known as a method for continuous mass production of thin films. The take-up type thin film production method is a method in which an elongated substrate is unwound from a feed roll and moved along a guide path to form a thin film on the moving substrate and then the substrate is wound up on a take-up roll.

The above-mentioned film formation techniques often involve the use of a vacuum apparatus. Therefore, attention must be paid also to the capabilities of a vacuum apparatus to increase the productivity of thin film formation. The important capabilities of a vacuum apparatus are, for example, a heating capability and a cooling capability.

For example, an evaporation source (typically, a crucible) used in the vacuum vapor deposition method must be heated during deposition, but it is desirable that the evaporation source be cooled after completion of the deposition to avoid unnecessary evaporation of materials and to start maintenance earlier. By doing so, reduction of the thin film production cost and improvement of the thin film productivity can be expected. Heater units or the like for heating various substrates also are required to be cooled for the same reasons.

The reasons why a vacuum chamber cannot be purged immediately to start the maintenance are, for example, that the degradation (in particular, oxidation) of components of a heat source such as an evaporation source must be prevented and the safety of workers must be ensured. The vacuum chamber can be purged with an inert gas such as nitrogen, but it takes too long for the heat source to cool down sufficiently. Therefore, the heat source should be cooled forcibly by some means.

### CITATION LIST

### Patent Literature

Patent Literature 1: JP 2010-255045 A

### SUMMARY OF INVENTION

### Technical Problem

A water-cooling type cooling device is often used to cool a heat source in a vacuum. However, the water-cooling type cooling device has the following drawbacks. If cooling water flows in the cooling device when the heat source must be heated, the heating efficiency decreases. When the flow of the cooling water is stopped to give priority to the heating efficiency, the cooling water in the pipe boils and the pressure in the pipe increases, which is dangerous. Instead of cooling water, a cooling liquid such as oil can also be used. However, if a cooling liquid such as oil spills in a vacuum chamber during maintenance, it is more difficult to remove contamination by the cooling liquid spills than to remove water spills.

Instead of such a water-cooling type cooling device, a gas-cooling type cooling device can also be used. Thermal expansion of gasses is more significant than that of liquids. Therefore, the problem of pressure rise in a pipe during the use of a heat source cannot be solved merely by using a gas-cooling type cooling device. It may be possible to communicate the inside of the cooling device with the atmosphere during the use of the heat source, but hot air may escape to the surroundings.

In view of the above circumstances, it is an object of the present invention to provide a technique for cooling a heat source in a vacuum.

### Solution to Problem

The present disclosure provides a vacuum apparatus including: a vacuum chamber; a heat source disposed inside the vacuum chamber; a cooling device that cools the heat source by circulation of a cooling gas; a gas feed line connected to the cooling device and extending outside the vacuum chamber; a cooling gas feeder that feeds the cooling gas to the cooling device through the gas feed line when the heat source is to be cooled; and a vacuum pump that evacuates the cooling device when the heat source is to be used.

### Advantageous Effects of Invention

According to the above-mentioned vacuum apparatus, the gas-cooling type cooling device is evacuated when the heat source is to be used. On the other hand, when the heat source is to be cooled, a cooling gas is fed into the cooling device from outside the vacuum while the vacuum surrounding the heat source is maintained. This configuration not only allows the heat source to be cooled when necessary but also allows the cooling device to be evacuated when the heat source is to be used, so that the risk of pressure rise due to the expansion of the cooling gas can be avoided.

### BRIEF DESCRIPTION OF DRAWINGS

FIG. 1A is a configuration diagram of a vacuum apparatus according to an embodiment of the present invention.

FIG. 1B is a configuration diagram of the vacuum apparatus according to the embodiment of the present invention (during cooling).

FIG. 2 is a configuration diagram of a vacuum apparatus according to a first modification.

FIG. 3 is a configuration diagram of a vacuum apparatus according to a second modification.

FIG. 4 is a configuration diagram of a vacuum apparatus according to a third modification.

FIG. 5 is a configuration diagram of a vacuum apparatus according to a fourth modification.

FIG. 6 is a configuration diagram of a vacuum apparatus according to a fifth modification.

FIG. 7 is a perspective view of an evaporation source as a heat source to be cooled in a vacuum.

FIG. 8 is a perspective view of a heater unit as a heat source to be cooled in a vacuum.

### DESCRIPTION OF EMBODIMENTS

A first aspect of the present disclosure provides a vacuum apparatus including: a vacuum chamber; a heat source disposed inside the vacuum chamber; a cooling device that cools the heat source by circulation of a cooling gas; a gas feed line connected to the cooling device and extending outside the vacuum chamber; a cooling gas feeder that feeds the cooling gas to the cooling device through the gas feed line when the heat source is to be cooled; and a vacuum pump that evacuates the cooling device when the heat source is to be used.

A second aspect of the present disclosure provides a vacuum apparatus as set forth in the first aspect, further including a switching unit provided in the gas feed line, the switching unit being configured to connect the cooling device and the cooling gas feeder when the heat source is to be cooled and to connect the cooling device and the vacuum pump when the heat source is to be used. According to the second aspect, it is possible to allow the cooling gas to flow in the cooling device or to evacuate the cooling device depending on the position of the switching unit. That is, it is possible not only to cool the heat source when necessary but also to evacuate the cooling device when the heat source is to be used, so that the risk of pressure rise due to the expansion of the cooling gas can be avoided. It is possible to maintain the vacuum state in the vacuum chamber both when the cooling gas is allowed to flow in the cooling device and when the cooling device is evacuated.

A third aspect of the present disclosure provides a vacuum apparatus as set forth in the first or second aspect, further including an evacuation line that is isolated from an atmosphere inside the vacuum chamber, the evacuation line being configured to connect the cooling device and the vacuum pump when the heat source is to be used.

A fourth aspect of the present disclosure provides a vacuum apparatus as set forth in the second aspect, further including an evacuation line that is isolated from an atmosphere inside the vacuum chamber, the evacuation line being configured to connect the cooling device and the vacuum pump when the heat source is to be used, wherein one end of the evacuation line is connected to the switching unit, and the switching unit is configured to connect one selected from the cooling gas feeder and the vacuum pump to the cooling device.

According to the third and fourth aspects, the cooling gas in the cooling device is not released into the vacuum chamber, and thus a decrease in the degree of the vacuum in the vacuum chamber can be prevented.

A fifth aspect of the present disclosure provides a vacuum apparatus as set forth in the second or fourth aspect, wherein the vacuum pump is connected to the vacuum chamber so that the vacuum chamber is evacuated by the vacuum pump, the switching unit is disposed inside the vacuum chamber and is capable of communicating the cooling device with the inside of the vacuum chamber, and the cooling device is evacuated through the inside of the vacuum chamber when the heat source is to be used. According to the fifth aspect, the cooling device is evacuated through the inside of the vacuum chamber.

A sixth aspect of the present disclosure provides a vacuum apparatus as set forth in any one of the second, fourth and fifth aspects, wherein the switching unit is a switching valve provided in the gas feed line inside the vacuum chamber. According to the sixth aspect, it is possible to reduce the time required to evacuate the cooling device while balancing the flow volume and flow velocity in the gas feed line.

A seventh aspect of the present disclosure provides a vacuum apparatus as set forth in any one of the first to sixth aspects, wherein the gas feed line includes a redundant line formed inside the vacuum chamber. The presence of the redundant line makes it possible to prevent heat damage of the switching unit.

A eighth aspect of the present disclosure provides a vacuum apparatus as set forth in any one of the second and fourth to sixth aspects, wherein the gas feed line includes a redundant line formed inside the vacuum chamber, and the redundant line is formed between the switching unit and the cooling device. According to the eighth aspect, it is possible to reliably prevent heat damage of the switching unit.

A ninth aspect of the present disclosure provides a vacuum apparatus as set forth in any one of the second and fourth to sixth aspects, further including a lead-in terminal that leads the gas feed line into the vacuum chamber from outside the vacuum chamber, wherein the gas feed line includes a redundant line formed inside the vacuum chamber, and the redundant line is formed between the switching unit and the lead-in terminal. According to the ninth aspect, it is possible to prevent heat damage of the lead-in terminal.

A tenth aspect of the present disclosure provides a vacuum apparatus as set forth in any one of the first to ninth aspects, further including another cooling device that cools the switching unit. According to the tenth aspect, it is possible to reliably protect the switching unit from heat.

An eleventh aspect of the present disclosure provides a vacuum apparatus as set forth in any one of the first to tenth aspects, wherein the gas feed line includes a return path that directs the cooling gas from the cooling device to the outside of the vacuum chamber, and the vacuum apparatus further includes a liquid-cooling type auxiliary cooling device that cools the return path inside or outside the vacuum chamber. The reduction in the temperature of the cooling gas by the auxiliary cooling device prevents the high temperature cooling gas from being released directly into a working environment, which is preferable to ensure safe operation.

A twelfth aspect of the present disclosure provides a vacuum apparatus as set forth in the eleventh aspect, wherein a gas pipe which is a part of the return path is bent or wound inside the auxiliary cooling device. According to the twelfth aspect, it is possible not only to increase the length of the gas feed line in the auxiliary cooling device but also to increase the efficiency of heat exchange between the cooling liquid held in the auxiliary cooling device and the cooling gas flowing in the gas feed line.

A thirteenth aspect of the present disclosure provides a vacuum apparatus as set forth in any one of the first to twelfth aspects, further including a temperature sensor that detects a temperature of the cooling gas that has passed through the cooling device, wherein the cooling gas feeder includes a flow rate controller that controls a flow rate of the cooling gas to be fed into the cooling device based on a result of the detection by the temperature sensor. According to the thirteenth aspect, it is possible to reduce the use of the cooling gas while preventing an excessive increase in the temperature of the gas pipe which is a part of the gas feed line.

A fourteenth aspect of the present disclosure provides a vacuum apparatus as set forth in any one of the first to twelfth aspects, wherein the vacuum apparatus is a vacuum vapor deposition apparatus, the heat source is an evaporation source that evaporates a material to be deposited on a substrate, and the evaporation source includes a crucible in which the material is to be placed.

A fifteenth aspect of the present disclosure provides a method for cooling a heat source in a vacuum using a cooling device capable of exerting a cooling function by circulation of a cooling gas, the method including steps of evacuating the cooling device when the heat source is to be used; and cooling the heat source by feeding the cooling gas into the cooling device from outside the vacuum and directing the cooling gas that has flowed through the cooling device to the outside of the vacuum, while maintaining the vacuum surrounding the heat source, when the heat source is to be cooled.

According to the fifteenth aspect, the gas-cooling type cooling device is evacuated when the heat source is to be used. On the other hand, when the heat source is to be cooled, the cooling gas is fed into the cooling device from outside the vacuum while the vacuum surrounding the heat source is maintained. Thus, it is possible not only to cool the heat source when necessary but also to evacuate the cooling device when the heat source is to be used, so that the risk of pressure rise due to the expansion of the cooling gas can be avoided.

A sixteenth aspect of the present disclosure provides a method for producing a thin film, including steps of: depositing particles coming from a film forming source on a substrate in a vacuum so as to form a thin film on the substrate, the film forming source including a cooling device capable of exerting a cooling function by circulation of a cooling gas; evacuating the cooling device when the depositing step is to be performed; and after the depositing step, cooling the film forming source by feeding the cooling gas into the cooling device from outside the vacuum and directing the cooling gas that has flowed through the cooling device to the outside of the vacuum, while maintaining the vacuum surrounding the film forming source.

According to the sixteenth aspect, it is possible to obtain the following effects in addition to the effects obtained in the fifteenth aspect. That is, it is possible to lower the temperature of the film forming source rapidly, and thus to reduce the time required for the maintenance of the vacuum apparatus and the time required before starting the preparation for the subsequent production. As a result, the productivity of thin film formation is increased.

Hereinafter, embodiments of the present invention will be described with reference to the drawings. The present invention is not limited to the following embodiments.

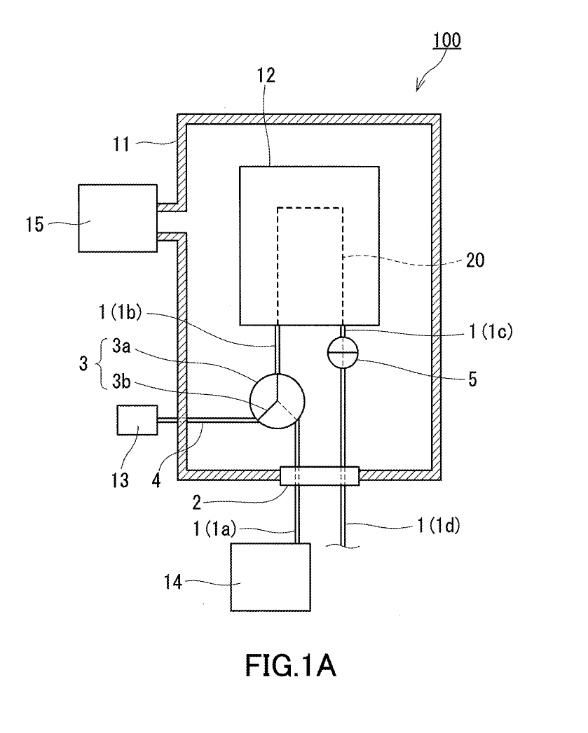

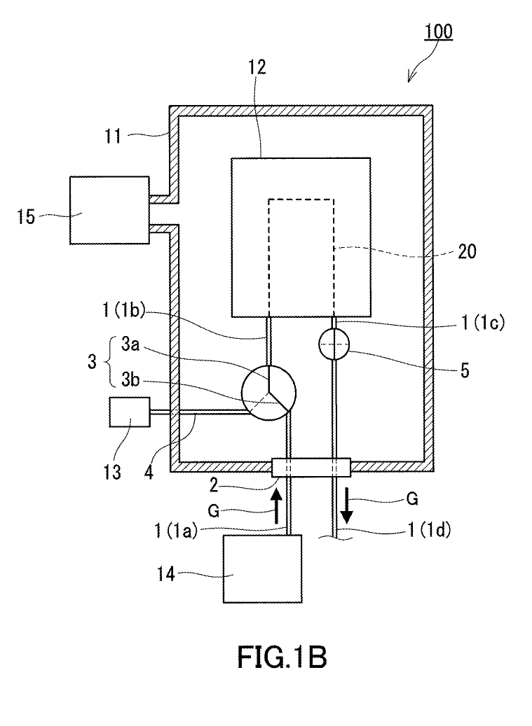

As shown in FIG. 1A, a vacuum apparatus 100 according to the present embodiment includes a vacuum chamber 11, a heat source 12, a cooling device 20, a gas feed line 1, an evacuation line 4, a first vacuum pump 13, a second vacuum pump 15, a cooling gas feeder 14, a switching valve 3 (a switching unit), and a stop valve 5. The heat source 12, the cooler 20, the switching valve 3, and the stop valve 5 are disposed inside the vacuum chamber 11. The second vacuum pump 15 is connected to the vacuum chamber 11. The vacuum chamber 11 is evacuated by the second vacuum pump 15.

The cooling device 20 is a gas-cooling type cooling device capable of exerting a function of cooling an object by circulation of a cooling gas. The cooling device 20 is responsible for cooling the heat source 12. The gas feed line 1 is connected to the cooling device 20 and extends from the inside of the vacuum chamber 11 to the outside thereof. The cooling gas feeder 14 is disposed outside the vacuum chamber 11, and is responsible for feeding the cooling gas to the cooling device 20 through the gas feed line 1 when the heat source 12 is to be cooled. The first vacuum pump 13 is used to evacuate the cooling device 20 when the heat source 12 is to be used. The switching valve 3 and the stop valve 5 are each provided in the gas feed line 1. The vacuum chamber 11 is provided with a lead-in terminal 2 (lead-in flange), though which the gas feed line 1 is led into the vacuum chamber 11.

When the heat source 12 is to be used, the switching valve 3 is controlled to be in the position shown in FIG. 1A. Thus, the cooling device 20 is connected to the first vacuum pump 13. When the heat source 12 is to be cooled, the switching valve 3 is controlled to be in the position shown in FIG. 1B. Thus, the cooling device 20 is connected to the cooling gas feeder 14. The cooling gas can be allowed to flow in the cooling device 20 or the cooling device 20 can be evacuated depending on the position of the switching valve 3. Thus, not only the heat source 12 can be cooled when necessary but also the cooling device 20 can be evacuated when the heat source 12 is to be used, so that the risk of pressure rise due to the expansion of the cooling gas can be avoided. The vacuum state in the vacuum chamber 11 can be maintained both when the cooling gas is allowed to flow in the cooling device 20 and when the cooling device 20 is evacuated.

The type, pressure, temperature, etc. of the cooling gas to be fed to the cooling device 20 are not particularly limited. Air, an inert gas, or the like can be used as the cooling gas. Air can be suitably used from an economic standpoint. Inert gasses such as nitrogen and rare gas can be suitably used to prevent corrosion of pipes, etc. It is desirable that the pressure of the cooling gas be high enough to create a flow that can contribute to the cooling of the heat source 12. The pressure of the cooling gas may be equal to or higher than the atmospheric pressure. For example, an excellent cooling effect can be obtained by feeding a cooling gas having a pressure of 2 to 5 atmospheres (a pressure at the outlet of the gas feeder 14) to the cooling device 20. The structure of the cooling gas line is simple and gas leakage hardly occurs. Therefore, a relatively high pressure cooling gas can be fed into the cooling device 20. In addition, the use of a relatively high pressure cooling gas makes it possible not only to smoothly feed the cooling gas to the cooling device 20 but also to smoothly direct the cooling gas that has flowed through the cooling device 20 to the outside of the vacuum chamber 11. The temperature of the cooling gas is typically room temperature. When the temperature of the heat source 12 to be cooled is high, it is only necessary that the cooling gas have a temperature near room temperature to be fully effective in cooling the heat source 12. In order to obtain a still higher cooling effect, the cooling gas may have a temperature lower than room temperature.

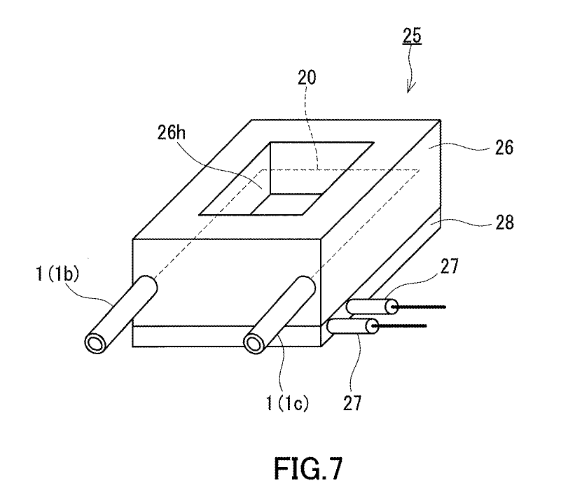

A specific example of the vacuum apparatus 100 is a vacuum vapor deposition apparatus. A specific example of the heat source 12 is an evaporation source that evaporates a material to be deposited on a substrate. As shown in FIG. 7, an evaporation source 25 as a specific example of the heat source 12 has a crucible 26 and a heater unit 28. The crucible 26 is made of a heat-resistant material such as metal, ceramic, or carbon. Examples of the metal include iron, steel, and stainless steel. The heater unit 28 is typically constituted by a resistance heater. The heater unit 28 may be constituted by a plane heater. The crucible 26 has a recessed portion 26h, and the material is placed in the recessed portion 26h. The heater unit 28 is bonded to the bottom of the crucible 26. When power is applied to the heater unit 28 through a terminal 27, the temperature of the heater unit 28 rises, so that the entire crucible 26 is heated. Thus, the material placed in the recessed portion 26h can be evaporated in a vacuum.

A gas flow passage (shown by a broken line) serving as the cooling device 20 is formed in the crucible 26. Since the gas flow passage forms a closed space, the cooling gas can pass through the crucible without leakage. An inlet and an outlet of the gas flow passage are formed in the crucible 26, and the gas feed line 1 is connected to the inlet and the outlet respectively. The gas flow passage serving as the cooling device 20 does not necessarily have to be formed inside the evaporation source 25. The cooling device 20 may be constituted by, for example, a cooling jacket covering the outer periphery of the evaporation source 25. A gas pipe wound around the evaporation source 25 also can be used as the cooling device 20.

The material placed in the crucible 26 can also be heated by an electron beam or a laser. In this case, the heater unit 28 may be omitted from the evaporation source 25. In sum, the heat source 12 may have a means for generating heat, or may be heated by energy supplied from outside.

As shown in FIG. 1A, the gas feed line 1 includes sections 1a to 1d. The sections 1a to 1d each can be constituted by a gas pipe. The sections 1a and 1b form a forward path that directs the cooling gas from the cooling gas feeder 14 to the cooling device 20. The sections 1c and 1d form a return path that directs the cooling gas from the cooling device 20 to the outside of the vacuum chamber 11. One end of the section 1a is connected to the cooling gas feeder 14 and the other end thereof is connected to the switching valve 3. One end of the section 1b is connected to the switching valve 3 and the other end thereof is connected to the cooling device 20. One end of the section 1c is connected to the cooling device 20 and the other end thereof is connected to the stop valve 5. One end of the section 1d is connected to the stop valve 5 and the other end thereof is located outside the vacuum chamber 11. The other end of the section 1d may be opened to the atmosphere, or may be connected to a gas collecting apparatus (not shown). Instead, the other end of the section 1d may be connected to the cooling gas feeder 14 so as to form a circulating cooling system. In the circulating cooling system, the heated cooling gas is not released into a working environment. Therefore, the safety of operation can be enhanced.

In the present embodiment, the switching valve 3 is provided in the forward path of the gas feed line 1, and the stop valve 5 is provided in the return path of the gas feed line 1. However, the locations of the switching valve 3 and the stop valve 5 are not particularly limited. For example, the switching valve 3 may be provided in the return path, and the stop valve 5 may be provided in the forward path.

The switching valve 3 has a housing 3a and a switching circuit 3b. The switching circuit 3b is configured to connect one selected from the section 1a of the gas feed line 1 and the evacuation line 4 to the section 1b of the gas feed line 1. When the section 1b is connected to the section 1a, the cooling gas feeder 14 communicates with the cooling device 20, so that the cooling gas can be fed from the cooling gas feeder 14 to the cooling device 20 through the gas feed line 1. When the section 1b is connected to the evacuation line 4, the cooling device 20 can be evacuated by the first vacuum pump 13.

The evacuation line 4 is a line isolated from the atmosphere inside the vacuum chamber 11, and a line for connecting the cooling device 20 to the first vacuum pump 13 when the heat source 12 is to be used. One end of the evacuation line 4 is connected to the switching valve 3 and the other end thereof is connected to the first vacuum pump 13. The evacuation line 4 is constituted by, for example, a gas pipe. The switching valve 3 connects one selected from the cooling gas feeder 14 and the first vacuum pump 13 to the cooling device 20. In this configuration, the cooling gas in the cooling device 20 is not released into the vacuum chamber 11, and thus a decrease in the degree of vacuum in the vacuum chamber 11 can be prevented. In addition, the load on the second vacuum pump 15 can be reduced.

In the vacuum apparatus 100, the heat source 12 is used and cooled by the following procedure. First, as shown in FIG. 1A, the cooling device 20 is evacuated when the heat source 12 is to be used. Specifically, the stop valve 5 is operated so that the return path of the gas feed line 1 is closed. The switching valve 3 is operated so that the evacuation line 4 is connected to the forward path (section 1b) of the gas feed line 1. The first vacuum pump 13 is driven to evacuate the cooling device 20. Thereby, the evacuation line 4, the cooling device 20, and portions (sections 1b and 1c) of the gas feed line 1 are in a vacuum state. As a result, it is possible to prevent the cooling device 20 from removing thermal energy from the heat source 12 and thus reducing the heating performance of the heat source 12. It is also possible to avoid the risk of pressure rise in the cooling device 20 and the gas feed line 1.

As shown in FIG. 1B, the cooling gas is fed to the cooling device 20 when the heat source 12 is to be cooled. Specifically, the switching valve 3 and the stop valve 5 are operated so that the entire gas feed line 1 becomes available. The evacuation line 4 is separated from the gas feed line 1 by the operation of the switching valve 3. The cooling gas is fed from the cooling gas feeder 14 to the cooling device 20 through the gas feed line 1. When the cooling gas flows in the cooling device 20, heat is exchanged between the cooling gas and the heat source 12, so that the heat source 12 can be cooled. During this heat exchange, the vacuum chamber 11 is maintained in a vacuum state by the second vacuum pump 15.

The switching valve 3 does not necessarily have to be provided in the gas feed line 1 inside the vacuum chamber 11. Even if the switching unit 3 is provided outside the vacuum chamber 11, the heat source 12 can be cooled by the same procedure as described above. It should be noted, however, that the following effects can be obtained when the switching valve 3 is disposed inside the vacuum chamber 11.

It is desirable that the thickness of the gas feed line 1 (thickness of the pipe) be almost constant in order to keep the flow of the cooling gas constant during the cooling of the heat source 12. If the pipe is too thin, it is difficult to allow a sufficient volume of the cooling gas to flow in the pipe. Conversely, if the pipe is too thick, it is difficult to allow the cooling gas to flow in the pipe at a sufficient velocity. The inner diameter of the pipes constituting the gas feed line 1 is, for example, in the range of ¼ to 1 inch. On the other hand, it is desirable that the gas feed line 1 be thick (have a high conductance) in order to achieve a rapid evacuation for the use of the heat source 12. However, it is not always appropriate to increase the thickness of the pipes along the path from the stop valve 5 to the first vacuum pump 13 because there are constraints for the cooling of the heat source 12. When the switching valve 3 is disposed inside the vacuum chamber 11, the section 1b of the gas feed line 1 can be made shorter and the evacuation line 4 can be made longer, if the total length of the pipes along the path from the cooling device 20 to the first vacuum pump 13 is fixed. That is, the section 1b of the gas feed line 1, which is a relatively thin pipe, is shortened, while the evacuation line 4, which is a relatively thick pipe, is lengthened. In this configuration, the time required to evacuate the cooling device 20 can be reduced while the flow volume and the flow velocity in the gas feed line 1 are well balanced.

When the vacuum apparatus 100 is a vacuum vapor deposition apparatus, a thin film can be produced by performing the following steps. First, particles coming from the evaporation source 25 (film forming source) including the cooling device 20 are deposited on a substrate in a vacuum so as to form a thin film on the substrate. The type of the substrate is not particularly limited. A resin film, a metal foil, or the like can be used as the substrate. The substrate may be a substrate having a thin film formed thereon. Examples of the substrate include current collectors of energy storage devices such as a lithium ion secondary battery and a lithium ion capacitor. An electrode plate having a current collector and an active material layer also may be used as the substrate.

When the particles are to be deposited on the substrate, that is, the depositing step is to be performed, the cooling device 20 is evacuated. After the depositing step, the evaporation source 25 is cooled by feeding the cooling gas into the cooling device 20 from outside the vacuum chamber 11 and directing the cooling gas that has flowed through the cooling device 20 to the outside of the vacuum chamber 11, while maintaining the vacuum surrounding the evaporation source 25 (the vacuum inside the vacuum chamber 11). Thereby, the temperature of the evaporation source 25 can be lowered rapidly, and therefore the time required for the maintenance of the vacuum apparatus 100 and the time required before starting the preparation for the subsequent production can be reduced. As a result, the productivity of thin film formation is increased.

The degree of vacuum in the vacuum chamber 11 during the use of the heat source 12 and the cooling thereof is not particularly limited. The degree of vacuum in the vacuum chamber 11 is maintained, for example, at 10⁻¹ to 10⁻⁴ Pa, which is a degree of vacuum suitable for the production of thin films.

Hereinafter, vacuum apparatuses according to modifications are described. In the following modifications, the same components as those of the vacuum apparatus 100 described with reference to FIG. 1A and FIG. 1B are designated by the same reference numerals, and the description thereof is omitted.

(First Modification)

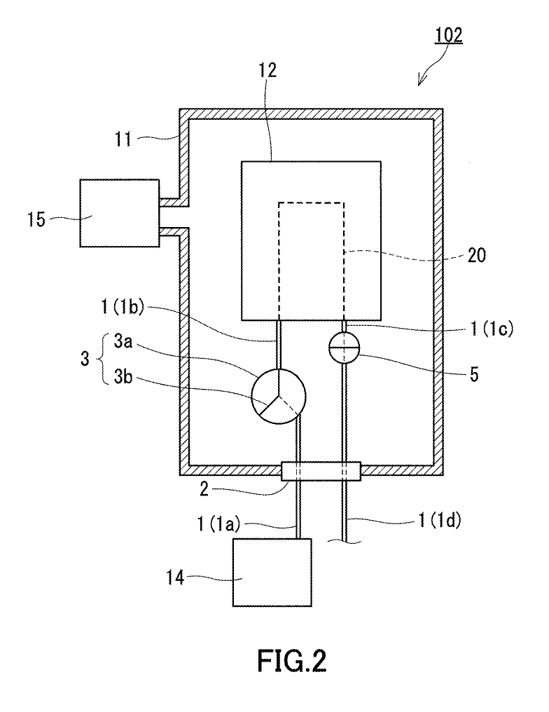

As shown in FIG. 2, in a vacuum apparatus 102 according to a first modification, the vacuum pump 15 is used to evacuate both the vacuum chamber 11 and the cooling device 20. According to this modification, the number of vacuum pumps is reduced and thereby the effect of reducing the cost can be expected. Since the configuration of the vacuum apparatus 102 is simpler than that of the vacuum apparatus 100 described above, the maintenance thereof is also easier.

As shown in FIG. 2, the vacuum pump 15 is connected to the vacuum chamber 11 so that the vacuum chamber 11 is evacuated by the vacuum pump 15. The switching valve 3 is disposed inside the vacuum chamber 11 and is capable of communicating the cooling device 20 with the inside of the vacuum chamber 11. Specifically, one of the ports of the switching valve 3 is exposed to the inside of the vacuum chamber 11. The other two ports of the switching valve 3 are each connected to the gas feed line 1. When the heat source 12 is to be used, the switching valve 3 and the stop valve 5 are respectively controlled to be in the positions shown in FIG. 2. Thereby, the cooling device 20 is evacuated through the inside of the vacuum chamber 11. When the heat source 12 is to be cooled, the switching valve 3 and the stop valve 5 are respectively controlled to be in the positions shown by broken lines. Thereby, the entire gas feed line 1 becomes available, which makes it possible to feed the cooling gas from the gas feeder 14 into the cooling device 20 while maintaining the vacuum inside the vacuum chamber 11.

(Second Modification)

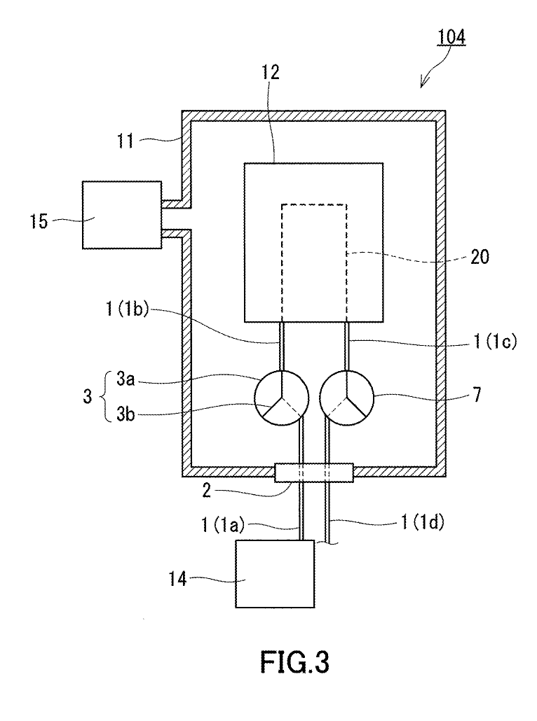

As shown in FIG. 3, a vacuum apparatus 104 according to a second modification is different from the vacuum apparatus 102 shown in FIG. 2, in that a second switching valve 7 is used instead of the stop valve 5.

The second switching valve 7 is disposed inside the vacuum chamber 11 and is capable of communicating the cooling device 20 with the inside of the vacuum chamber 11, as in the case of the switching valve 3 (first switching valve). Specifically, one of the ports of the second switching valve 7 is exposed to the inside of the vacuum chamber 11. The other two ports of the second switching valve 7 are each connected to the gas feed line 1. When the heat source 12 is to be used, the switching valves 3 and 7 are respectively controlled to be in the positions shown in FIG. 3. Thereby, the cooling device 20 is evacuated through the inside of the vacuum chamber 11. When the heat source 12 is to be cooled, the switching valves 3 and 7 are respectively controlled to be in the positions shown by broken lines. Thereby, the entire gas feed line 1 becomes available, which makes it possible to feed the cooling gas from the gas feeder 14 to the cooling device 20 while maintaining the vacuum inside the vacuum chamber 11.

According to this modification, the cooling device 20 can be evacuated from both the forward path and the return path of the gas feed line 1. Therefore, rapid and reliable evacuation can be performed, and the risk of pressure rise in the cooling device 20 and the gas feed line 1 can be reliably avoided during the use of the heat source 12. In the vacuum apparatus 100 shown in FIG. 1, the stop valve 5 can be replaced by the second switching valve 7.

(Third Modification)

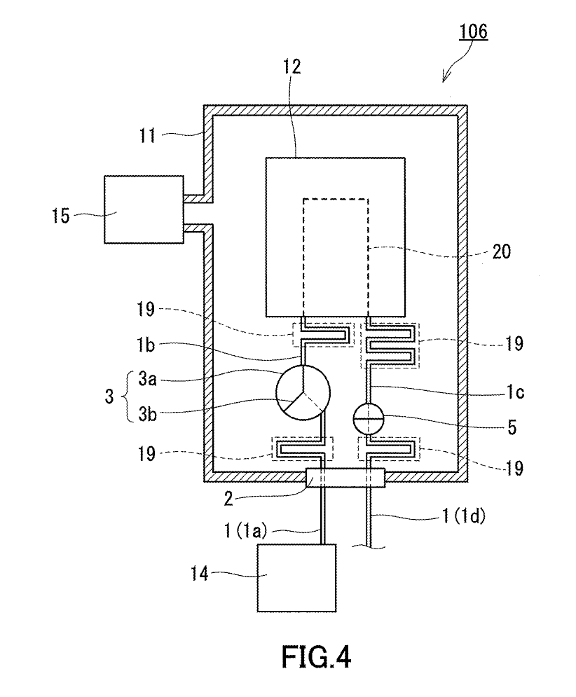

As shown in FIG. 4, a vacuum apparatus 106 according to a third modification is different from the vacuum apparatus 102 (FIG. 2) according to the first modification, in that the vacuum apparatus 106 further includes a redundant line 19. The gas feed line 1 includes the redundant line 19 formed inside the vacuum chamber 11. Thanks to the presence of the redundant line 19, heat is hardly transferred from the heat source 12 to the switching valve 3 and the stop valve 5. Therefore, it is possible to prevent heat damage of the switching valve 3 and the stop valve 5.

The redundant line 19 may be formed in any part of the gas feed line 1. However, it is preferable that the redundant line 19 be formed between the cooling device 20 and the switching valve 3 in the gas feed line 1 in order to protect the switching valve 3 from heat. Likewise, it is preferable that the redundant line 19 be formed between the cooling device 20 and the stop valve 5 in the gas feed line 1 in order to protect the stop valve 5 from heat. In this modification, the redundant lines 19 are formed in the section 1b and the section 1c, respectively, of the gas feed line 1.

The redundant line 19 may be formed between the switching valve 3 and the lead-in terminal 2 in the gas feed line 1. That is, the redundant line 19 may be formed in the section 1a of the gas feed line 1. In this case, it is possible to prevent heat damage of the lead-in terminal 2. For the same reason, the redundant line 19 may be formed between the stop valve 5 and the lead-in terminal 2 in the gas feed line 1. That is, the redundant line 19 may be formed in the section 1d of the gas feed line 1.

The redundant line 19 prevents the cooling device 20 from being connected to the switching valve 3 with the shortest distance. Likewise, the redundant line 19 prevents the cooling device 20 from being connected to the stop valve 5 with the shortest distance. The structure of the redundant line 19 is not particularly limited as long as it can exert this function. For example, the redundant line 19 can be provided by bending, corrugating, or spirally winding a gas pipe which is a part of the gas feed line 1.

It is also effective to cool the switching valve 3 with another cooling device in order to protect the switching valve 3 from heat. Likewise, it is also effective to cool the stop valve 5 with another cooling device in order to protect the stop valve 5 from heat. An example of such a cooling device is a liquid-cooling type cooling device. An example of the liquid-cooling type cooling device is a device provided with a cooling plate and a liquid-cooling pipe welded to the cooling plate. The cooling function is exerted by allowing a cooling liquid such as water to flow in the liquid-cooling pipe. The switching valve 3 or the stop valve 5 can be cooled by screwing the switching valve 3 or the stop valve 5 to the cooling plate. A heat conductive sheet may be sandwiched between the switching valve 3 and the cooling plate. Likewise, a heat conductive sheet may be sandwiched between the stop valve 5 and the cooling plate. It is also possible to cool the valve using a Peltier device instead of the liquid-cooling pipe.

(Fourth Modification)

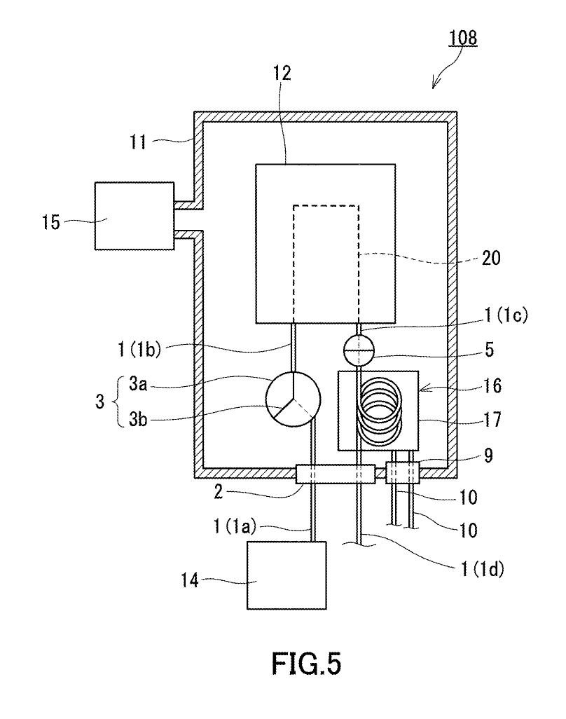

As shown in FIG. 5, a vacuum apparatus 108 according to a fourth modification further includes a liquid-cooling type auxiliary cooling device 16 that cools the gas feed line 1. As described above, the gas feed line 1 includes a forward path that directs the cooling gas from the cooling gas feeder 14 to the cooling device 20 and a return path that directs the cooling gas from the cooling device 20 to the outside of the vacuum chamber 11. The forward path is formed of the sections 1a and 1b. The return path is formed of the sections 1c and 1d. In this modification, the auxiliary cooling device 16 is disposed inside the vacuum chamber 11 and is configured to cool the return path (section 1d). The relatively high temperature cooling gas that has flowed through the cooling device 20 flows in the return path (sections 1c and 1d) of the gas feed line 1. The reduction in the temperature of the cooling gas by the auxiliary cooling device 16 prevents the high temperature cooling gas from being released directly into a working environment, which is preferable to ensure safe operation. Even if the auxiliary cooling device 16 is provided outside the vacuum chamber 11, the same effect can be obtained.

The auxiliary cooling device 16 is, for example, a liquid-cooling type cooling device. The auxiliary cooling device 16 includes a housing 17, a lead-in terminal 9 (lead-in flange), and cooling liquid feed pipes 10. The return path (section 1d) of the gas feed line 1 penetrates the housing 17. The cooling liquid is fed into the housing 17 from outside the vacuum chamber 11 through the cooling liquid feed pipe 10. The cooling liquid feed pipe 10 is led into the vacuum chamber 11 from outside the vacuum chamber 11 through the lead-in terminal 9. Two cooling liquid feed pipes 10 are connected to the housing 17 so that the cooling liquid can be circulated in the housing 17. The type of the cooling liquid is not particularly limited, and any known cooling liquid such as water, oil, brine, or liquid nitrogen can be used as appropriate.

A gas pipe which is a part of the return path of the gas feed line 1 is exposed to the inside of the housing 17 of the auxiliary cooling device 16. Specifically, the gas pipe is bent or spirally wound in the housing 17. This shape can not only increase the length of the gas feed line 1 in the housing 17 but also increase the efficiency of heat exchange between the cooling liquid held in the housing 17 and the cooling gas flowing in the gas feed line 1.

(Fifth Modification)

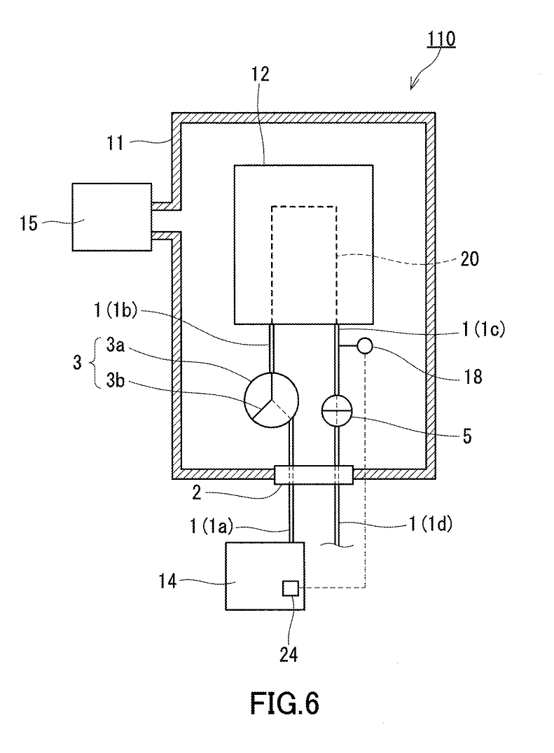

As shown in FIG. 6, a vacuum apparatus 110 according to a fifth modification further includes a temperature sensor 18 that detects the temperature of the cooling gas that has flowed through the cooling device 20, in addition to the configuration of the vacuum apparatus 102 shown in FIG. 2. The cooling gas feeder 14 includes a flow rate controller 24 that controls the flow rate of the cooling gas to be fed into the cooling device 20 based on the result of the detection by the temperature sensor 18. According to the temperature sensor 18 and the flow rate controller 24, it is possible to reduce the use of the cooling gas while preventing an excessive increase in the temperature of the gas pipe which is a part of the gas feed line 1.

The temperature sensor 18 is provided between the cooling device 20 and the stop valve 5, that is, in the return path (section 1e) of the gas feed line 1. The temperature sensor 18 detects the temperature of the gas feed line 1 (specifically, the temperature of the gas pipe) or the temperature in the gas feed line 1. That is, the temperature sensor 18 may detect the temperature of the cooling gas directly or indirectly. Detection signals output from the temperature sensor 18 are input to the flow rate controller 24. The flow rate controller 24 determines the temperature of the cooling gas based on the input detection signals. When the determined temperature is higher than a threshold temperature, the flow rate of the cooling gas to be fed into the cooling device 20 is increased. When the determined temperature is lower than the threshold temperature, the flow rate of the cooling gas to be fed into the cooling device 20 is reduced. The higher the determined temperature is, the more the flow rate of the cooling gas to be fed into the cooling device 20 is increased.

This control can also be applied to the other vacuum apparatuses 100, 102, 104, 106 and 108.

(Others)

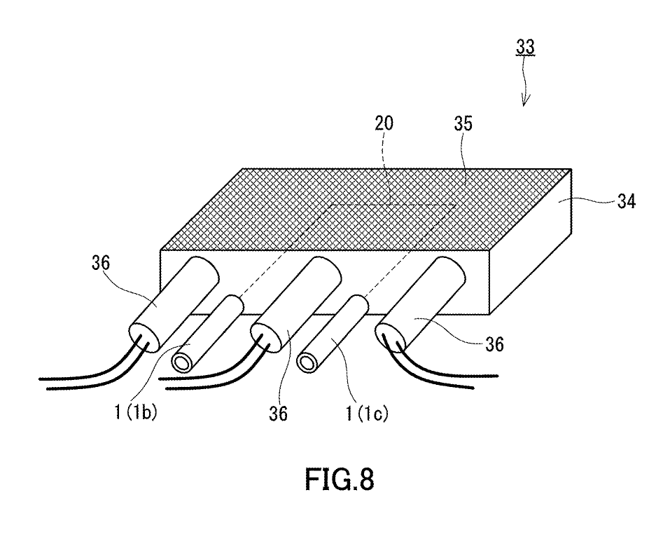

The heat source 12 to be cooled after the use thereof is not limited to an evaporation source. As shown in FIG. 8, another example of the heat source 12 is a heater unit 33 for heating the substrate. The heater unit 33 includes a heater block 34 and a plurality of rod heaters 36. The heater block 34 is made of, for example, a heat-resistant material that can be used for the crucible 26 described with reference to FIG. 7. The upper surface 35 of the heater block 34 is a surface to face the substrate. The substrate can be heated by bringing the substrate close to or in contact with the upper surface 35. The upper surface 35 may be subjected to a treatment for increasing the efficiency of heating the substrate. An example of such a treatment is formation of a black coating on the upper surface 35 to increase the emissivity.

The rod heaters 36 are inserted into slots provided in the heater block 34. The heater block 34 is entirely heated by the heaters 36. A gas flow passage (shown by a broken line) serving as the cooling device 20 is formed in the heater block 34. Since the gas flow passage forms a closed space, the cooling gas can pass through the heater block 34 without leakage. The heater block 34 has an inlet and an outlet of the gas flow passage formed therein, and the gas feed line 1 is connected to the inlet and the outlet respectively.

### INDUSTRIAL APPLICABILITY

Vacuum apparatuses to which the present invention is applicable are not limited to vacuum vapor deposition apparatuses. The vacuum apparatuses include a wide range of apparatuses utilizing the properties of the vacuum state. Examples of such vacuum apparatuses include a vacuum film formation apparatus, a vacuum processing apparatus, a vacuum metallurgical apparatus, a vacuum chemical apparatus, a surface analysis apparatus, and a vacuum test apparatus. Examples of the vacuum film formation apparatus include a vapor deposition apparatus, a sputtering apparatus, and a CVD apparatus. Examples of the vacuum processing apparatus include a dry etching apparatus, an ashing apparatus, and an ion implantation apparatus. Examples of the vacuum metallurgical apparatus include a melting apparatus and a heat treatment apparatus. Examples of the vacuum chemical apparatus include a reaction apparatus and a distillation apparatus. Examples of the surface analysis apparatus include an X-ray photoelectron spectroscopy apparatus and an electron probe microanalyzer. Examples of the vacuum test apparatus include a fatigue test apparatus.

1. A vacuum apparatus comprising:
a vacuum chamber;
a heat source disposed inside the vacuum chamber;
a cooling device configured to cool the heat source by circulation of a cooling gas;
a gas feed line connected to the cooling device and extending outside the vacuum chamber;
a cooling gas feeder configured to feed the cooling gas to the cooling device through the gas feed line when the heat source is to be cooled; and
a vacuum pump configured to evacuate the cooling device when the heat source is to be used.

2. The vacuum apparatus according to claim 1, further comprising a switching unit provided in the gas feed line, the switching unit being configured to connect the cooling device and the cooling gas feeder when the heat source is to be cooled and to connect the cooling device and the vacuum pump when the heat source is to be used.

3. The vacuum apparatus according to claim 1, further comprising an evacuation line isolated from an atmosphere inside the vacuum chamber, the evacuation line being configured to connect the cooling device and the vacuum pump when the heat source is to be used.

4. The vacuum apparatus according to claim 2, further comprising an evacuation line isolated from an atmosphere inside the vacuum chamber, the evacuation line being configured to connect the cooling device and the vacuum pump when the heat source is to be used, wherein
one end of the evacuation line is connected to the switching unit, and
the switching unit is configured to connect one selected from the cooling gas feeder and the vacuum pump to the cooling device.

5. The vacuum apparatus according to claim 2, wherein
the vacuum pump is connected to the vacuum chamber so that the vacuum chamber is evacuated by the vacuum pump,
the switching unit is disposed inside the vacuum chamber and is capable of communicating the cooling device with the inside of the vacuum chamber, and
the cooling device is evacuated through the inside of the vacuum chamber when the heat source is to be used.

6. The vacuum apparatus according to claim 2, wherein the switching unit is a switching valve provided in the gas feed line inside the vacuum chamber.

7. The vacuum apparatus according to claim 1, wherein the gas feed line includes a redundant line formed inside the vacuum chamber.

8. The vacuum apparatus according to claim 2, wherein
the gas feed line includes a redundant line formed inside the vacuum chamber, and
the redundant line is formed between the switching unit and the cooling device.

9. The vacuum apparatus according to claim 2, further comprising a lead-in terminal configured to lead the gas feed line into the vacuum chamber from outside the vacuum chamber, wherein
the gas feed line includes a redundant line formed inside the vacuum chamber, and
the redundant line is formed between the switching unit and the lead-in terminal.

10. The vacuum apparatus according to claim 1, further comprising another cooling device configured to cool the switching unit.

11. The vacuum apparatus according to claim 1, wherein
the gas feed line includes a return path configured to direct the cooling gas from the cooling device to the outside of the vacuum chamber, and
the vacuum apparatus further comprises a liquid-cooling type auxiliary cooling device configured to cool the return path inside or outside the vacuum chamber.

12. The vacuum apparatus according to claim 11, wherein a gas pipe which is a part of the return path is bent or wound inside the auxiliary cooling device.

13. The vacuum apparatus according to claim 1, further comprising a temperature sensor configured to detect a temperature of the cooling gas that has passed through the cooling device, wherein
the cooling gas feeder includes a flow rate controller configured to control a flow rate of the cooling gas to be fed into the cooling device based on a result of the detection by the temperature sensor.

14. The vacuum apparatus according to claim 1, wherein
the vacuum apparatus is a vacuum vapor deposition apparatus,
the heat source is an evaporation source configured to evaporate a material to be deposited on a substrate, and
the evaporation source includes a crucible in which the material is to be placed.

15. A method for cooling a heat source in a vacuum using a cooling device capable of exerting a cooling function by circulation of a cooling gas, the method comprising steps of:
evacuating the cooling device when the heat source is to be used; and
cooling the heat source by feeding the cooling gas into the cooling device from outside the vacuum and directing the cooling gas that has flowed through the cooling device to the outside of the vacuum, while maintaining the vacuum surrounding the heat source, when the heat source is to be cooled.

16. A method for producing a thin film, comprising steps of;
depositing particles coming from a film forming source on a substrate in a vacuum so as to form a thin film on the substrate, the film forming source including a cooling device capable of exerting a cooling function by circulation of a cooling gas;
evacuating the cooling device when the depositing step is to be performed; and
after the depositing step, cooling the film forming source by feeding the cooling gas into the cooling device from outside the vacuum and directing the cooling gas that has flowed through the cooling device to the outside of the vacuum, while maintaining the vacuum surrounding the film forming source.
